(19) United States
(12) Patent Application Publication
(10) Pub. No.: US 2022/0190549 A1
(43) Pub. Date: Jun. 16, 2022

(54) SEMICONDUCTOR OPTICAL SIGNAL AMPLIFIER

(71) Applicant: ROHM CO., LTD., Kyoto (JP)

(72) Inventors: Fumiya NAGASAWA, Kyoto (JP); Hiroshi SEKIGUCHI, Kyoto (JP); Makoto TAKAMURA, Kyoto (JP)

(73) Assignee: ROHM CO., LTD., Kyoto (JP)

(21) Appl. No.: 17/546,980

(22) Filed: Dec. 9, 2021

(30) Foreign Application Priority Data
Dec. 15, 2020 (JP) 2020-207730

(51) Int. Cl. H01S 5/026; H01S 5/50; H04B 10/50; H01L 31/0312

(52) U.S. Cl. CPC H01S 5/0262; H01L 31/0312; H04B 10/503; H01S 5/50

(57) ABSTRACT

The present disclosure provides a semiconductor optical signal amplifier for amplifying a light having an energy smaller than a band gap energy. The semiconductor optical signal amplifier includes: a first end surface; a second end surface, arranged apart from the first end surface; a first semiconductor region and a second semiconductor region, arranged between the first end surface and the second end surface; an active layer, arranged between the first end surface and the second end surface, and sandwiched between the first semiconductor region and the second semiconductor region, made of an indirect transition type semiconductor that amplifies a signal intensity of an input light by stimulated emission; a first electrode, connected to the first semiconductor region; and a second electrode, connected to the second semiconductor region and detecting a change in a carrier density in the active layer by a potential difference from the first electrode.

### TECHNICAL FIELD

The disclosure relates to a semiconductor optical signal amplifier.

### BACKGROUND

For a light receiving element for visible light to near-infrared light, a photodiode (PD) is used, or an avalanche PD in which a reverse bias is applied to the PD and having higher sensitivity and an amplification function is used. On the other hand, a semiconductor optical amplifier (SOA) used in optical communications has an optical amplification function and is also used as a light receiving element.

### PRIOR ART DOCUMENT

### [Patent Publication]

[Patent document 1] Japan Patent Publication No. 04-25824
[Patent document 2] Japan Patent Publication No. 62-44833
[Patent document 3] Japan Patent Publication No. 03-96917
[Patent document 4] Japan Patent Publication No. 2003-533896

### SUMMARY

### Problems to be Solved by the Disclosure

A light receiving wavelength of a photodiode (PD) or an avalanche photodiode (PD) is determined by electron transition between band gaps. That is to say, via electron transition from an energy-stable state to a high-energy state, the band gap width determines an upper limit of the light receiving wavelength.

On the other hand, a semiconductor optical amplifier (SOA) uses components such as indium phosphide (InP) and gallium arsenide (GaAs) to form a direct transition type semiconductor for a semiconductor laser. Thus, an indirect transition type semiconductor such as silicon (Si) cannot be used for a substrate. As a result, the selection for substrates is limited and costly. Moreover, a light receiving wavelength of an SOA also employs electron transition between the band gaps and hence relies on the band gap.

Embodiments of the disclosure provide a semiconductor optical signal amplifier for amplifying a light having an energy smaller than a band gap energy.

### Technical Means for Solving the Problem

According to an aspect of the disclosure, a semiconductor optical signal amplifier includes: an active layer, made of an indirect transition type semiconductor that amplifies a signal intensity of an input light by stimulated emission; and a detection electrode, detecting a change in a carrier density in the active layer, wherein the active layer has a point defect that serves as a recombination center forming an energy level in a band gap of the indirect transition type semiconductor, and a light with an energy smaller than a band gap energy of the indirect transition type semiconductor is amplified by transition via the energy level.

According to another aspect of the disclosure, a semiconductor optical signal amplifier includes: an active layer, made of an amorphous semiconductor that amplifies a signal intensity of an input light by stimulated emission; and a detection electrode, detecting a change in a carrier density in the active layer, wherein the active layer has a point defect that serves as a recombination center forming an energy level in a band gap of the amorphous semiconductor, and a light with an energy smaller than a band gap energy of the amorphous semiconductor is amplified by transition via the energy level.

According to yet another aspect of the disclosure, a semiconductor optical signal amplifier includes: a first end surface; a second end surface, arranged apart from the first end surface; a first semiconductor region of a first conductive type, arranged between the first end surface and the second end surface; a second semiconductor region of a second conductive type opposite to the first conductive type, arranged between the first end surface and the second end surface; an active layer, arranged between the first end surface and the second end surface, and sandwiched between the first semiconductor region and the second semiconductor region, the active layer made of an indirect transition type semiconductor that amplifies a signal intensity of an input light by stimulated emission; a first electrode, connected to the first semiconductor region; and a second electrode, connected to the second semiconductor region and detecting a change in a carrier density in the active layer by a potential difference from the first electrode, wherein the active layer has a point defect that serves as a recombination center forming an energy level in a band gap of the indirect transition type semiconductor, and a light with an energy smaller than a band gap energy of the indirect transition type semiconductor is amplified by transition via the energy level.

### Effects of the Disclosure

According to the embodiments of the disclosure, a semiconductor optical signal amplifier for amplifying a light having an energy smaller than a band gap energy is provided.

### BRIEF DESCRIPTION OF THE DRAWINGS

FIG. 1A is a section diagram of a semiconductor optical signal amplifier according to a first embodiment, and FIG. 1B is an equivalent circuit diagram of a semiconductor optical signal amplifier according to the first embodiment;

FIG. 2 is a diagram of an energy gap structure in a state of thermal equilibrium of a semiconductor optical signal amplifier according to the first embodiment;

FIG. 3 is a diagram of an energy gap structure in a state of forward bias of a semiconductor optical signal amplifier according to the first embodiment;

FIG. 4A is a section diagram of a semiconductor optical signal amplifier according to a first variation example of the first embodiment, and FIG. 4B is a section diagram of a second variation example of a semiconductor optical signal amplifier according to the first embodiment;

FIG. 5 is a section diagram of a semiconductor optical signal amplifier according to a second embodiment;

FIG. 6 is a section diagram of a semiconductor optical signal amplifier according to a third embodiment;

FIG. 7A is a schematic diagram of light intensity distribution Ph from a light receiving terminal to an output terminal, and FIG. 7B is a schematic diagram of electron number distribution Nn from a light receiving terminal to an output terminal in a semiconductor optical signal amplifier according to the third embodiment;

FIG. 8 is a section diagram of a semiconductor optical signal amplifier according to a fourth embodiment;

FIG. 9A is a diagram of an energy gap structure in a state of thermal equilibrium of a semiconductor optical signal amplifier according to a fifth embodiment, and FIG. 9B is a section diagram of a semiconductor optical signal amplifier according to the fifth embodiment;

FIG. 10A is a diagram of an energy gap structure of a direct transition type semiconductor, and FIG. 10B is a diagram of an energy gap structure of an indirect transition type semiconductor;

FIG. 11 is a diagram for illustrating transition of electrons during capturing and recombination processes;

FIG. 12A is an illustrative diagram of a light excitation process, and FIG. 12B is an illustrative diagram of capturing and recombination processes of localized energy levels;

FIG. 13 is a relationship diagram of lattice constants, band gap energies and light wavelengths of the 2-element, 3-element, and 4-element III-V semiconductor crystals;

FIG. 14 is an example of light receiving wavelength bands when individual semiconductor crystals are configured as light receiving elements;

FIG. 15A is a schematic structural diagram of a crystal structure of nitrogen-vacancy (NV) pairs (diamond NV centers) in diamond crystals, and FIG. 15B is a schematic diagram of energy levels in NV pairs (diamond NV centers) in diamond crystals

FIG. 16A is a diagram of an energy gap structure of a pn junction of 4H—SiC or 6H—SiC having Si vacancy defects and a diagram illustrating energy levels, and FIG. 16B is a diagram of measurement results (energy-wavelength dependency) of photoluminescence (PL) and electroluminescence (EL) of a pn function of 4H—SiC or 6H—SiC having Si vacancy defects; and

FIG. 17A is a diagram of a crystal structure of divacancy defects in 4H—SiC, and FIG. 17B is a diagram of measurement results (wavelength dependency) of PL of a pn junction of 4H—SiC having divacancy defects;

FIG. 18A is a diagram illustrating energy levels formed by erbium ion (Er³⁺) in amorphous Si, and FIG. 18B is a diagram of measurement results (wavelength dependency) of PL formed by erbium ion (Er³⁺) in amorphous Si; and

FIG. 19 is a diagram illustrating energy levels when Cd, Cd—O and S are added to GaP.

### DETAILED DESCRIPTION OF THE DISCLOSURE

Details of the embodiments of the disclosure are given with the accompanying drawings below. In the following description regarding the drawings, the same or similar denotation is assigned to the same or similar part. It should be noted that the drawings are schematic and illustrative. The embodiments are examples for illustrating specific configurations of devices or methods based on technical concepts, and do not specifically define materials, shapes, structures, configurations and sizes of the components. Various modifications may be made to these embodiments.

### First Embodiment

### (Semiconductor Optical Signal Amplifier)

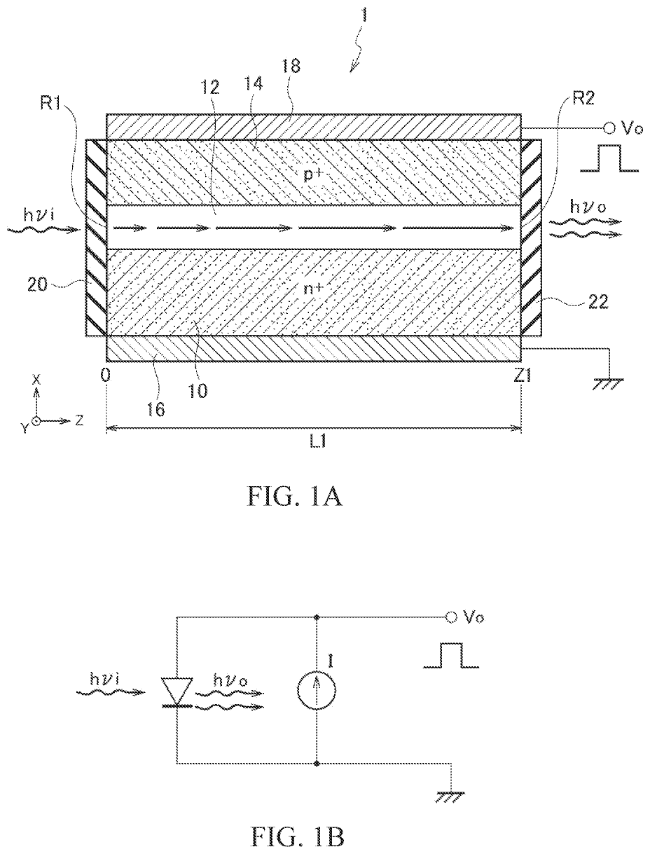

FIG. 1A shows a section structure and FIG. 1B shows an equivalent circuit diagram of a semiconductor optical signal amplifier (SOA) 1 according to a first embodiment.

The SOA 1 of the first embodiment is made of an indirect transition type semiconductor, and includes an active layer (AL) 12 that amplifies a signal intensity of an input light hvi by stimulated emission, and detection electrodes 16 and 18 detecting a change in a carrier density in the active layer 12.

The active layer 12 has a point defect that serves as a recombination center forming an energy level in a band gap of the indirect transition type semiconductor. A light with an energy smaller than a band gap energy of the indirect transition type semiconductor is amplified by transition via the energy level.

As shown in FIG. 1B, the SOA 1 of the first embodiment conducts a forward current I that is greater than or equal to the threshold current for realizing stimulated emission. In this state, the input light hvi is incident into the active layer 12 and an amplified coherent output light hvo is outputted. In FIG. 1B, the arrow in the active layer 12 illustratively represents a situation of gradually amplifying the input light hvi in the Z direction. Moreover, the change in the carrier density in the active layer 12 is detected via the voltage Vo between the main electrodes 16 and 18 of the SOA 1.

The SOA 1 of the first embodiment includes a first end surface R1, a second end surface R2, an n-type first semiconductor region 10, a p-type second semiconductor region 14, the active layer 12, the first electrode 16 and the second electrode 18.

A direction from the first end surface R1 to the second end surface R2 is defined as the Z direction, a direction parallel to the first end surface R1 from the first semiconductor region 10 to the second semiconductor region 14 is defined as the X direction, and a direction perpendicular to the Z direction and the X direction is defined as the Y direction.

The second end surface R2 is arranged apart from the first end surface R1 by a distance Z1 in the Z direction. The n-type first semiconductor region 10 is arranged between the first end surface R1 and the second end surface R2. The p-type second semiconductor region 14 is also arranged between the first end surface R1 and the second end surface R2.

The active layer 12 is arranged between the first end surface R1 and the second end surface R2 and is sandwiched between the first semiconductor region 10 and the second semiconductor region 14. The active layer 12 is made of an indirect transition type semiconductor that amplifies a signal intensity of the input light hvi by stimulated emission.

The first electrode 16 is connected to the first semiconductor region 10. The second electrode 18 is connected to the second semiconductor region 14. The second electrode 18 can detect the change in the carrier density in the active layer 12 via the voltage Vo of the first electrode 16.

The active layer 12 has a point defect that serves as a recombination center forming an energy level in a band gap of the indirect transition type semiconductor.

The SOA 1 of the first embodiment can amplify a light with an energy smaller than a band gap energy of an indirect transition type semiconductor by transition via an energy level.

Moreover, the SOA 1 of the first embodiment may also include a first anti-reflective coating film 20 arranged on the first end surface R1, and a second anti-reflective coating film 22 arranged on the second end surface R2.

The first semiconductor region 10, the second semiconductor region 14 and the active layer 12 may also extend in a stripe shape in the Z direction.

The active layer 12 has an optical amplifying medium that amplifies the signal intensity of the input light hvi. The optical amplifying medium used as a medium for implementing stimulated emission has point defects that realize inverse distribution. (Charactersitics_gain of the semiconductor optical signal amplifier and saturation of light output)

In the SOA 1 of the first embodiment, as shown in FIG. 1A, an active region structure is used the same as semiconductor laser, a current is injected to inject electrons and holes to thereby transition from a conduction band of an excitation energy level of a high electron energy to a valence electron band of a low energy level, accordingly achieving optical amplification.

The active layer 12 is a p-type or n-type semiconductor layer, and is a layer that includes light emitting recombination centers. The light emitting recombination centers are introduced via point defects. For example, in the active layer 12, an energy level formed by light emitting recombination centers is formed (omitted from the drawing).

In the SOA 1 of the first embodiment, a light is amplified by transition between energy levels formed by light emitting recombination centers, and so optical amplification can be achieved even for a long-wavelength light with an energy smaller than a band gap energy.

In the presence of an opposite absorption light that amplifies a light by transition from an excitation level to a ground state level by stimulated emission, and in the absence of absorption light of transition from a ground state level to an excitation level, natural emission of transition from an excitation level to a ground state level is realized according to interaction of vibration of field zero-points.

In FIG. 1B, if an input power of a light where Z=0 is set to Pin and an output power of Z=Z1=Z1 is set to Pout, the input light hvi is propagated in the active layer 12 while being amplified by stimulated emission, and the output power Pout is expressed as below.

Pout=Pin·EXP(∫₀^{L1}ξgdZ) (1)

Herein, ξ represents the power of the light propagated within a light confinement factor of the ratio of the active layer 12; g is the ratio of amplifying the power of a light per unit length, and is a function of the density and wavelength of the injected electrons. Since the density of injected electrons is a field function, the gain coefficient g is also a field function. In particular, the gain coefficient g, when uniform relative to Z, is expressed as below.

Pout=Pin·exp(ξgL1) (2)

Herein, when the gain coefficient g>0, the light intensity increases exponentially, and light amplification occurs. In a bulk semiconductor, the approximation of the gain coefficient g relative to the density N of injected electrons is expressed as below.

g=A(N−N_{g}) (3)

Herein, N_{g} is the density of electrons needed for generating a positive gain, and A is a ratio constant. The amplification ratio (gain G) is expressed in a unit of decibels (dB) as below.

G=Pout/Pin=exp(ξgL1)=10 ξgL1/In(10) (dB) (4)

The discussion above relates to a situation where the gain coefficient g is fixed relative to the space. However, if the input power Pin increases, the output power Pout becomes extremely large, and the density of electrons decreases as stimulated emission becomes drastic. As a result, the gain decreases (gain saturation) compared to when the gain coefficient g decreases and the input power Pin is smaller.

The light emitting recombination centers in the active layer 12 can be formed by electron beam irradiation or ion injection. The light emitting recombination centers are formed by, for example, composite defects of vacancies, rare earth ions and impurity atoms.

In the SOA 1 of the first embodiment, optical amplification can be achieved by injecting carriers into the active layer 12 and then injecting a current to the light emitting recombination centers.

By injecting a current to the light emitting recombination centers, stimulated emission is realized in the active layer 12, and optical amplification is then produced by the incidence of the incident light hvi. A method of detecting a change in the density of carriers of the optical amplifying medium 12 by electricity to voltage can be used to detect the carrier consumption at this point.

With the SOA 1 according to the first embodiment, a light is amplified by transition between energy levels formed by light emitting recombination centers, and so optical amplification can be achieved even for a long-wavelength light with an energy smaller than a band gap energy.

The SOA 1 according to the first embodiment can still achieve light reception even with respect to a long-wavelength light with an energy smaller than a band gap energy, and can function as a light receiving element for a long-wavelength light with an energy smaller than a band gap energy.

Moreover, the light emitting recombination centers refer to point defects (intrinsic or extrinsic point defects) that form an energy level in the band gap of the active layer 12 and emit a light by electrical and optical excitation. Intrinsic defects are composite defects of compounds referred to as vacancy or reverse defects. Moreover, extrinsic defects are defects originated from impurities. The same applies to the description of a semiconductor optical signal amplifier in the description below.

### [Inhibition for Reflection at an End Surface]

The SOA 1 of the first embodiment is a traveling wave amplifier. The SOA 1 of the first embodiment has a mirrorless structure that resonates both ends of a Fabry-Perot laser.

To inhibit reflection at an end surface, the SOA 1 of the first embodiment may also include an anti-reflection coating film on an end surface.

The first semiconductor region 10, the active layer 12 and the second semiconductor region 14 may have a first end surface R1, and have an anti-reflection coating film 20 on the first end surface R1, as shown in FIG. 1A.

Moreover, the first semiconductor region 10, the active layer 12 and the second semiconductor region 14 may have a second end surface R2 opposite to the first end surface R1, and have an anti-reflection coating film 22 on the second end surface R2, as shown in FIG. 1A.

The anti-reflection coating films 20 and 22 include single-layer and multi-layer dielectric layers. For example, silicon oxide (SiOx) or silicon nitride (SiNx) may be used as the material of the dielectric layer.

Moreover, the first electrode (En) 16 is connected to the first semiconductor region 10, and the second electrode (Ep) 18 is connected to the second semiconductor region 14.

### [Structure of Energy Gap]

### (State of Thermal Equilibrium)

FIG. 2 shows a diagram of an energy gap structure in a state of thermal equilibrium of a semiconductor optical signal amplifier according to the first embodiment.

The active layer 12 is a p-type or n-type semiconductor layer, and is a layer that includes a light emitting recombination centers. Energy levels Et1 and Et2 formed by the light emitting recombination centers are formed in the active layer 12.

In the SOA 1 of the first embodiment, a light is amplified by transition between energy levels Et1 and Et2, and so optical amplification can be achieved even for a long-wavelength light with an energy smaller than a band gap energy.

The SOA 1 according to the first embodiment can still achieve light reception even with respect to a long-wavelength light with an energy smaller than a band gap energy, and can function as a light receiving element for a long-wavelength light with an energy smaller than a band gap energy.

In the SOA 1 of the first embodiment, the energy levels Et1 and Et2 are formed in the energy gap of the active layer 12 by the light emitting recombination centers. Moreover, the p⁺-type semiconductor layer 14 and the n⁺-type semiconductor layer 10 are both degenerate semiconductors.

In the state of thermal equilibrium, as shown in FIG. 2, a Fermi level E_{F} is arranged in a valence band of the second semiconductor region 14 and in a conduction band of the first semiconductor region 10.

### (State of Forward Bias)

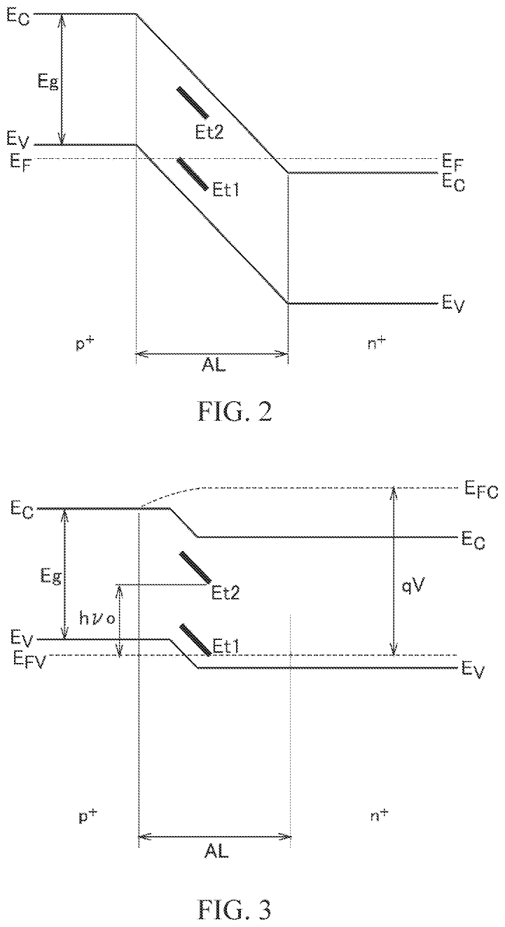

FIG. 3 shows a diagram of an energy gap structure in a state of forward bias of the SOA 1 according to the first embodiment. By applying forward bias potential qV, a Fermi level E_{FC} of the first semiconductor region 10 is sufficiently deep compared to a Fermi level E_{FV} of the second semiconductor region 14, and rises in the conduction band. At an energy level lower than the Fermi level E_{FC} of the first semiconductor region 10, electrons filling up to a conduction band E_{C} form inverse distribution. At an energy level higher than the Fermi level E_{FV} of the second semiconductor region 14, electrons filling up to a valance band E_{V} also form inverse distribution.

The electrons filling between the energy level lower than the Fermi level E_{FC} of the first semiconductor region 10 and the conduction band E_{C} are likely to transition to the valence band E_{V}, and recombine with the holes filling between the energy level higher than the Fermi level E_{FV} of the second semiconductor region 14 and the valence band E_{V}. At this point, a light can be amplified by the transition between energy levels Et1 and Et2 by stimulated emission, and so optical amplification can be accordingly achieved even for a long-wavelength light with an energy smaller than a band gap energy.

For example, if defects that become light emitting recombination centers of a 1.5 μm band are introduced into the band gap of Si, a light emitting element that receives a light at the 1.5 μm band can be realized by Si.

### (Variation Example of the First Embodiment)

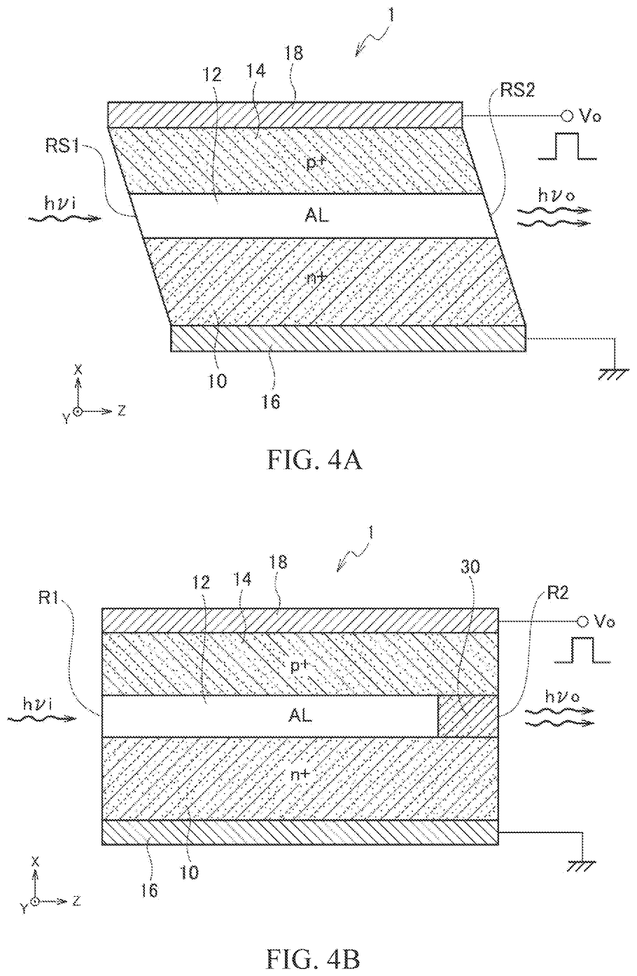

FIG. 4A shows a section diagram of a first variation example of the SOA 1 of the first embodiment.

A first end surface RS1 and a second end surface RS2 are parallel to each other and are inclined relative to an X-Y plane formed by the X axis and the Y axis.

The SOA 1 of the first variation example of the first embodiment has inclined surfaces, and can thus inhibit reflection at the end surfaces.

The SOA 1 of the first variation example of the first embodiment has the inclined end surfaces, and can thus realize a traveling wave optical amplifier the same as the mirrorless structure that resonates both ends of a Fabry-Perot laser. The remaining parts of the structure are the same as those of the first embodiment.

FIG. 4B shows a section diagram of a second variation example of the SOA 1 of the first embodiment.

To inhibit reflection at an end surface, the SOA 1 of the second variation example of the first embodiment may further include a window region 30 in vicinity of the second end surface R2 of the active layer 12. The window region 30 is a medium through which the output light hvo of amplified coherent light passes through the input light hvi.

The SOA 1 of the second variation example of the first embodiment has the window region 30 in vicinity of the second end surface R2 of the active layer 12, and can thus realize a traveling wave optical amplifier the same as the mirrorless structure that resonates both ends of a Fabry-Perot laser. The remaining parts of the structure are the same as those of the first embodiment.

### Second Embodiment

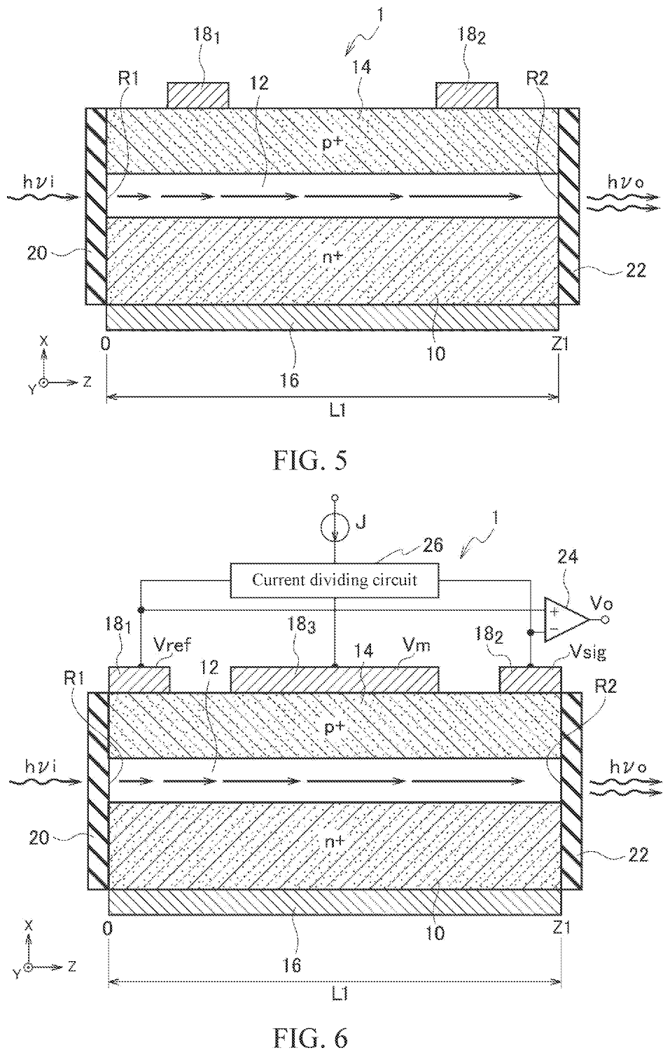

FIG. 5 shows a section diagram of the SOA 1 according to a second embodiment.

In the SOA 1 of the second embodiment, the second electrode 18 is divided into two electrodes 18₁ and 18₂. The first electrode 16 is set to as fixed potential, for example, ground potential. If a forward current flows between the second electrode 18₁ and the first electrode 16 and between the second electrode 18₂ and the first electrode 16, in a state in which optical amplification can be realized, it is set that the input light hvi can be incident, and optical amplification is produced by stimulated emission in the active layer 12. If the input light hvi is incident, carrier distribution deviation may be caused in the active layer 12 in the Z direction, and a change in the carrier distribution occurs. As a result, a potential difference is generated in the active layer 12. By increasing the gain in the Z direction, the amplified coherent output light hvo can be obtained. With the change in the carrier density of the active layer 12, the potential difference can be detected as an electrical change between the second electrodes 18₁ and 18₂. The remaining parts of the structure are the same as those of the first embodiment.

The active layer 12 is a p-type or n-type semiconductor layer, and is a layer that includes light emitting recombination centers. The light emitting recombination centers are introduced via point defects.

In the SOA 1 of the second embodiment, a light is amplified by transition between energy levels, and so optical amplification can be achieved even for a long-wavelength light with an energy smaller than a band gap energy.

The SOA 1 according to the second embodiment can still achieve light reception even with respect to a long-wavelength light with an energy smaller than a band gap energy, and can function as a light receiving element for a long-wavelength light with an energy smaller than a band gap energy.

The SOA 1 of the second embodiment can provide a semiconductor light receiving element and a semiconductor optical signal amplifier using light emitting recombination centers.

### Third Embodiment

FIG. 6 shows a section diagram of the SOA 1 according to a third embodiment.

In the SOA 1 of the third embodiment, the second electrode 18 is divided into three second electrodes 18₁, 18₂ and 18₃. The first electrode 16 is set to as fixed potential, for example, ground potential.

A current dividing circuit 26 is connected to a constant current source J. Densities of currents conducted between the second electrode 18₁ and the first electrode 16, between the second electrode 18₂ and the first electrode 16 and between the second electrode 18₃ and the first electrode 16 are designed to be equal, and the three second electrodes 18₁, 18₂ and 18₃ are connected to the current dividing circuit 26. If the potential of the second electrode 18₁ is set to Vref, the potential of the second electrode 18₂ is set to Vsig and the potential of the second electrode 18₃ is set to Vm, the potentials Vsig and Vref as an electrical change between the second electrodes 18₁ and 18₂ are inputted to a comparator 24 to accordingly obtain a detected voltage Vo.

If forward currents flow between the second electrode 18₁ and the first electrode 16, between the second electrode 18₂ and the first electrode 16 and between the second electrode 18₃ and the first electrode 16, in a state in which optical amplification can be realized, it is set that the input light hvi can be incident, and optical amplification is produced by stimulated emission in the active layer 12. If the input light hvi is incident, carrier distribution deviation may be caused in the active layer 12 in the Z direction, and a change in the carrier distribution occurs. As a result, a potential difference is generated in the active layer 12. By increasing the gain in the Z direction, the amplified coherent output light hvo can be obtained. Due to the change in the carrier density of the active layer 12, the potentials Vsig and Vref as an electrical change between the second electrodes 18₁ and 18₂ are inputted to a comparator 24, and the voltage Vo can be accordingly obtained by differential detection. The remaining parts of the structure are the same as those of the first embodiment.

In the SOA 1 of the third embodiment, a light is amplified by transition between energy levels, and so optical amplification can be achieved even for a long-wavelength light with an energy smaller than a band gap energy.

The SOA 1 according to the third embodiment can still achieve light reception even with respect to a long-wavelength light with an energy smaller than a band gap energy, and can function as a light receiving element for a long-wavelength light with an energy smaller than a band gap energy.

The SOA 1 of the third embodiment can provide a semiconductor light receiving element and a semiconductor optical signal amplifier using light emitting recombination centers.

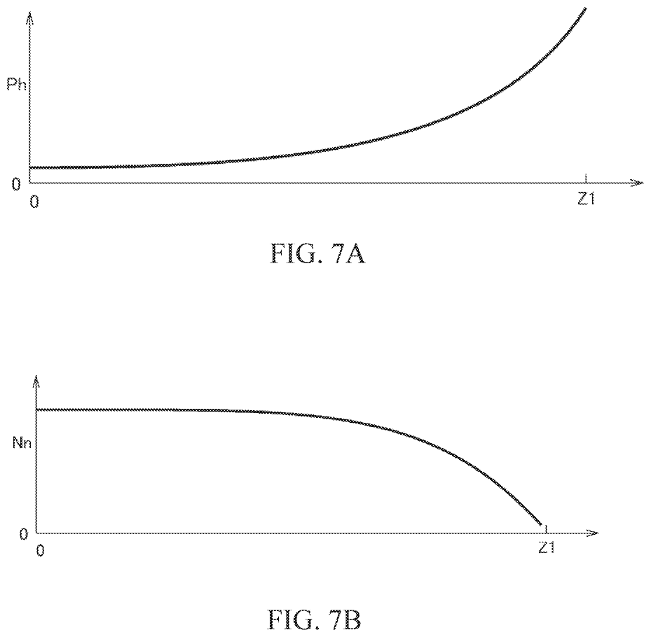

FIG. 7A shows a diagram illustrating light intensity distribution Ph from a light receiving terminal to an output terminal in the SOA 1 of the third embodiment. Moreover, FIG. 7B shows a diagram illustrating electron number distribution Nn from the light receiving terminal to the output terminal in the SOA 1 of the third embodiment. The light intensity distribution Ph from the light receiving terminal to the output terminal gradually increases in the Z direction along with the optical amplification by stimulated emission. On the other hand, along with the optical amplification by stimulated emission and the increase of the light intensity distribution Ph, loss of carriers (electrons) due to recombination is caused, and so the electron number distribution Nn gradually decreases in the Z direction.

### Fourth Embodiment

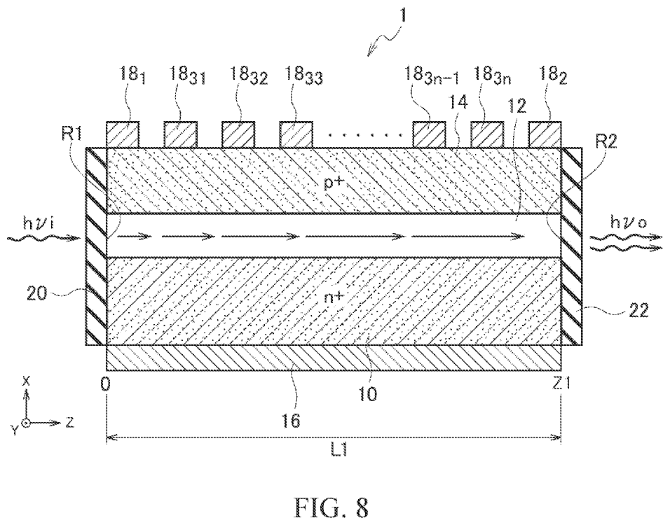

FIG. 8 shows a section diagram of the SOA 1 according to a fourth embodiment.

In the SOA 1 of the fourth embodiment, the second electrode 18 is divided into a plurality of second electrodes 18₁, 18₂, 18₃₁, 18₃₂,18₃₃, . . . , 18₃ₙ₋₁ and 18₃ₙ. The first electrode 16 is set to as fixed potential, for example, ground potential. The same as the third embodiment, the second electrodes 18₁, 18₂, 18₃₁, 18₃₂,18₃₃, . . . , 18₃ₙ₋₁ and 18₃ₙ may also be connected a current dividing circuit connected to a constant current source J. Similarly, densities of currents conducted between the second electrode 18₁ and the first electrode 16, between the second electrode 18₂ and the first electrode 16 and between the second electrode 18₃₁, 18₃₂,18₃₃, . . . , 18₃ₙ₋₁ and 18₃ₙ and the first electrode 16 are designed to be equal, and the divided second electrodes 18₁, 18₂, 18₃₁, 18₃₂,18₃₃, . . . , 18₃ₙ₋₁ and 18₃ₙ are connected to the current dividing circuit. The voltage Vo can be obtained by differential detection as an electrical change between the second electrodes 18₁ and 18₂.

If forward currents flow between the second electrode 18₁ and the first electrode 16, between the second electrode 18₂ and the first electrode 16 and between the second electrode 18₃₁, 18₃₂,18₃₃, . . . , 18₃ₙ₋₁ and 18₃ₙ and the first electrode 16, in a state in which optical amplification can be realized, it is set that the input light hvi can be incident, and optical amplification is produced by stimulated emission in the active layer 12. If the input light hvi is incident, carrier distribution deviation may be caused in the active layer 12 in the Z direction, and a change in the carrier distribution occurs. As a result, a potential difference is generated in the active layer 12. By increasing the gain in the Z direction, the amplified coherent output light hvo can be obtained. Due to the change in the carrier density of the active layer 12, the potential difference as an electrical change between the second electrodes 18₁ and 18₂ is inputted to the comparator, and the voltage Vo can be accordingly obtained by differential detection. The remaining parts of the structure are the same as those of the first embodiment.

In the SOA 1 of the fourth embodiment, a light is amplified by transition between energy levels, and so optical amplification can be achieved even for a long-wavelength light with an energy smaller than a band gap energy.

### Fifth Embodiment

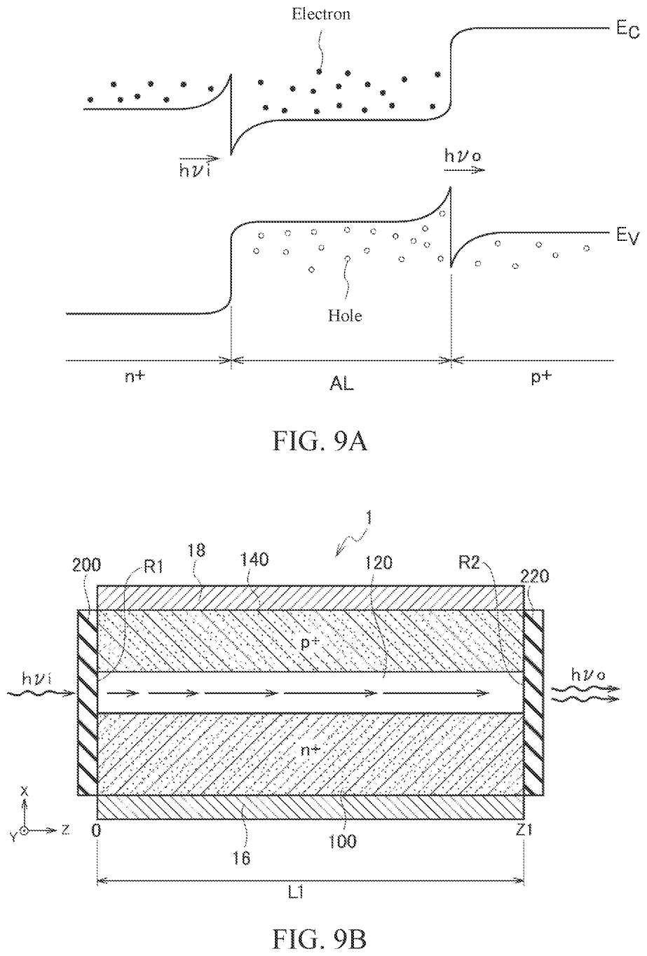

FIG. 9A shows a diagram of an energy gap structure in a state of thermal equilibrium of the SOA 1 according to the fifth embodiment. Moreover, FIG. 9B shows a section diagram of the SOA 1 according to the fifth embodiment.

The SOA 1 of the fifth embodiment is made of an indirect transition type semiconductor, and includes a active layer (AL) 120 that amplifies a signal intensity of an input light by stimulated emission, and detection electrodes 16 and 18 detecting a change in a carrier density in the active layer 120.

The active layer 120 has a point defect that serves as a recombination center forming an energy level in a band gap of the indirect transition type semiconductor. A light with an energy smaller than a band gap energy of the indirect transition type semiconductor is amplified by transition via the energy level.

Similar to that shown in FIG. 1B, the SOA 1 of the fifth embodiment conducts a forward current I that is greater than or equal to the threshold current for realizing stimulated emission. In this state, the input light hvi is incident into the active layer 120 and an amplified coherent output light hvo is outputted. Moreover, the change in the carrier density in the active layer 12 is detected by detecting the voltage Vo between the main electrodes 16 and 18 of the SOA 1.

In addition, the SOA 1 of the fifth embodiment includes a first end surface R1, a second end surface R2, an n-type first semiconductor region 100, a p-type second semiconductor region 140, the active layer 120, the first electrode 16 and the second electrode 18.

Herein, the active layer 120 has a band gap narrower than that of the first semiconductor region 100 and the second semiconductor region 140.

The second end surface R2 is arranged apart from the first end surface R1 by a distance Z1 in the Z direction. The n-type first semiconductor region 100 is arranged between the first end surface R1 and the second end surface R2. The p-type second semiconductor region 140 is also arranged between the first end surface R1 and the second end surface R2.

The active layer 120 is arranged between the first end surface R1 and the second end surface R2 and is sandwiched between the first semiconductor region 100 and the second semiconductor region 140. The active layer 120 is made of an indirect transition type semiconductor that amplifies a signal intensity of the input light hvi by stimulated emission.

The first electrode 16 is connected to the first semiconductor region 100. The second electrode 18 is connected to the second semiconductor region 140. The second electrode 18 can detect the change in the carrier density in the active layer 120 via the voltage Vo of the first electrode 16.

The active layer 120 has a point defect that serves as a recombination center forming an energy level in a band gap of the indirect transition type semiconductor.

Moreover, the SOA 1 of the fifth embodiment may also include a first anti-reflective coating film 20 arranged on the first end surface R1, and a second anti-reflective coating film 22 arranged on the second end surface R2.

The active layer 120 has an optical amplifying medium that amplifies the signal intensity of the input light hvi. An optical amplifying medium used as a medium for implementing stimulated emission has point defects that realize inverse distribution.

In the SOA 1 of the fifth embodiment, as shown in FIG. 9A, an active region structure including a dual heterojunction is used the same as semiconductor laser, a current is injected to inject electrons and holes to thereby transition from a conduction band of an excitation energy level of a higher electron energy to a valence electron band of a low energy level, accordingly achieving optical amplification.

The active layer 120 is a p-type or n-type semiconductor layer, and is a layer that includes light emitting recombination centers. The light emitting recombination centers are introduced via point defects. For example, in the active layer 120, energy levels Et1 and Et2 (omitted from the drawing) formed by light emitting recombination centers are formed.

In the SOA 1 of the fifth embodiment, a light is amplified by transition between energy levels Et1 and Et2, and so optical amplification can be achieved even for a long-wavelength light with an energy smaller than a band gap energy.

In FIG. 9B, if an input power of a light where Z=0 is set to Pin and an output power of Z=Z1=Z1 is set to Pout, the input light hvi is propagated in the active layer 120 while being amplified by stimulated emission, and the output power Pout is also expressed as (1).

In the SOA 1 of the fifth embodiment, since the active layer 12 has a band gap narrower than that of the first semiconductor region 100 and the second semiconductor region 140, the light confinement efficiency is higher.

The SOA 1 of the fifth embodiment can amplify a light with an energy smaller than a band gap energy of an indirect transition type semiconductor by transition via energy levels.

### (Direct Transition Type and Indirect Transition Type)

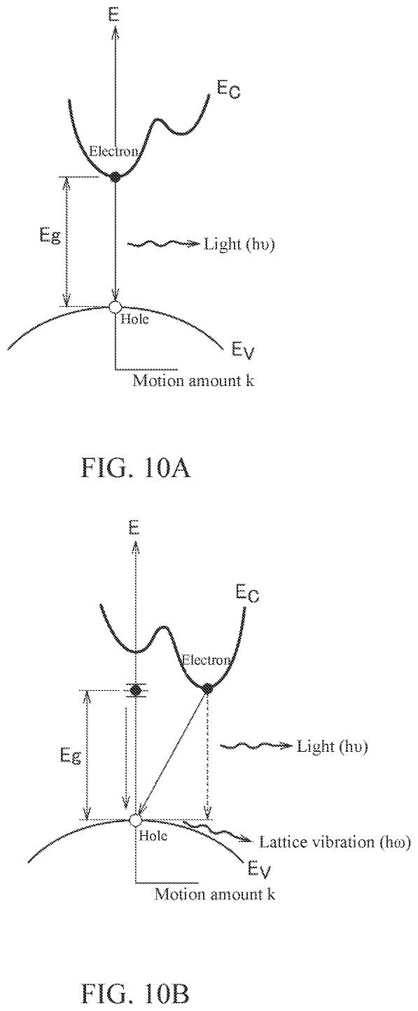

FIG. 10A shows a diagram of an energy gap structure of direct transition type semiconductor crystals. In addition, FIG. 10B shows a diagram of an energy gap structure of indirect transition type semiconductor crystals.

The band gap structure of semiconductor crystals is an intrinsic structure of crystals, and can be classified into a direct transition type and an indirect transition type. The direct transition type crystals are crystals that are advantageous in vertical transition in a k-space, and can be used as light emitting diodes or laser diodes providing effective energy bands. In contrast, in a situation where light emission is performed by indirect transition type crystals that involve horizontal transition, the indirect transition type crystals are not suitable for performing efficient light emission because a change also occurs in energy unnecessary for light emission, that is, heat or sound. However, in a direct transition semiconductor, because transition between bands determines the wavelength, wavelength selectivity is not provided.

In the SOA 1 of this embodiment, point defects that become light emitting recombination centers are introduced into the active layer including indirect transition crystals, a light is amplified by transition between energy levels, and so optical amplification can be achieved even for a long-wavelength light with an energy smaller than a band gap energy of the active layer.

### (Transition of Electrons During Capturing and Recombination Processes)

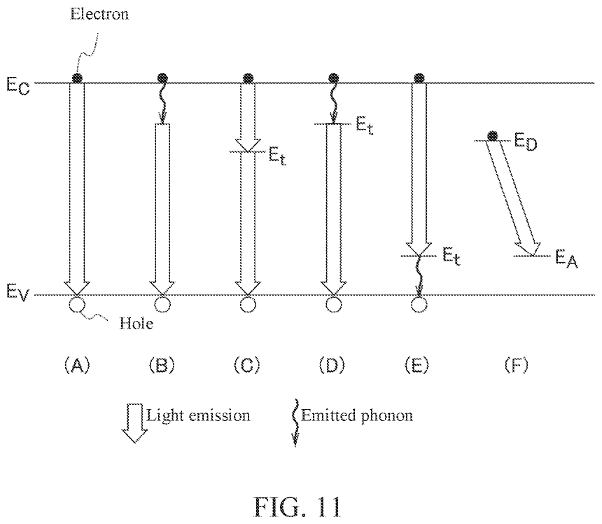

FIG. 11 shows a diagram of transition of electrons during capturing and recombination processes.

In any of cases of recombination of electrons with holes and capturing another in a localized energy level or capturing and recombination with another can be accompanied with energy emission of some form. Forms of such energy emission can be classified into three following categories: (1) a process of emitting a light, (2) a non-light emitting process of emitting phonons, and (3) a non-light emitting process of transition of transferring energy to other electrons.

In FIG. 11, (A) and (B) represent direct recombination processes of emitted light. Direct recombination between energy levels is a light emitting process for becoming light emitting centers.

In FIG. 11, (C), (D) and (E) are light emitting processes of the localized energy level Et becoming a light emitting center, wherein the light emitting processes are generated when emission is fully larger than a transition energy of phonons. After one carrier (for example, an electron) is captured at the localized energy level Et in the light emitting processes of (C), (D) and (E) in FIG. 11, another carrier (a hole) can be captured at the energy level Et. As a result, recombination of two carriers can be performed in the localized energy level Et. The localized energy level Et is a light emitting recombination center.

In FIG. 11, (F) is a light emitting process in which a donor energy level E_{D} and an acceptor E_{A} become a light emitting center as a localized energy level. The donor energy level E_{D} and the acceptor E_{A} as a light emitting center also serves as a light emitting recombination center.

In the SOA 1 of this embodiment, since a light is amplified by transition via energy levels, a light emitting process of any one or a combination of (C) to (F) in FIG. 11 is applied.

### (Light Excitation Process and Capturing and Recombination Processes of Localized Energy Levels)

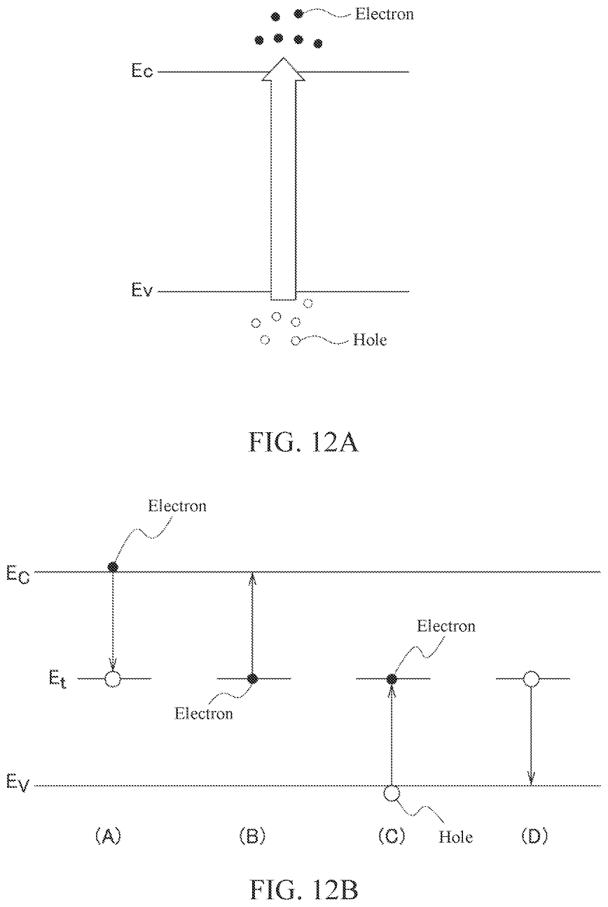

FIG. 12A shows a illustrative diagram of a light excitation process between the valence band E_{V} and the conduction band E_{C}. In an excited state, electrons are distributed in excess at the conduction band E_{C}, and holes are distributed in excess at the valance band E_{V}. FIG. 12B shows an illustrative diagram of capturing and recombination processes of the localized energy level Et. (A) represents a capturing process of an electron from the conduction band E_{C} to the localized energy level Et. (B) represents an emission process of an electron from the localized energy level Et to the conduction band E_{C}. (C) represents a capturing process of a hole from the valence band E_{V} to the localized energy level Et. (D) represents an emission process of a hole from the localized energy level Et to the valence band E_{V}.

### (2-Element, 3-Element and 4-Element III-V Semiconductor Crystals)

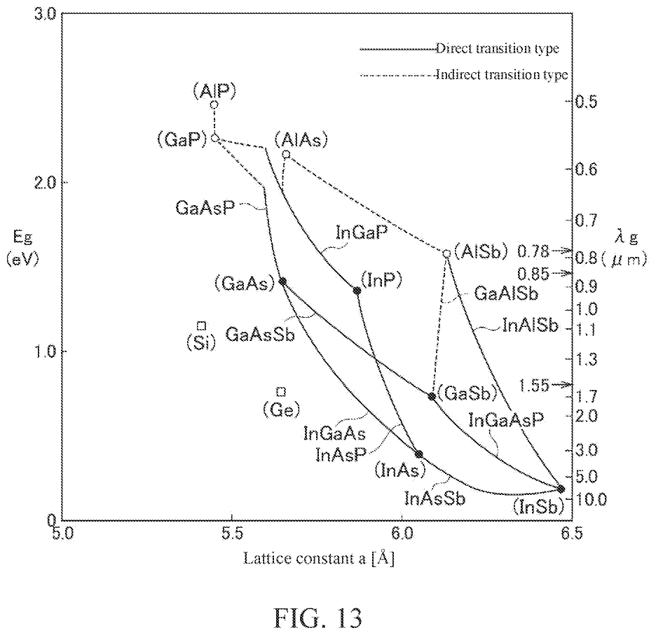

FIG. 13 shows a relationship diagram of lattice constants, band gap energies and light wavelengths of the 2-element, 3-element, and 4-element III-V semiconductor crystals. The dotted lines indicate examples of indirect transition type crystals of 2-element, 3-element and 4-element III-V group semiconductor crystals. The solid lines are examples of direct transition type crystals.

In the SOA 1 of this embodiment, the indirect transition type crystals of the 2-element, 3-element, and 4-element III-V semiconductor crystals shown in FIG. 13 can be applied as the active layer including indirect transition type crystals.

In the SOA 1 of this embodiment, point defects that become light emitting recombination centers are introduced into the active layer including the indirect transition type crystals of the 2-element, 3-element, and 4-element III-V semiconductor crystals shown in FIG. 13, a light is amplified by transition between energy levels, and so optical amplification can be achieved even for a long-wavelength light with an energy smaller than a band gap energy of the active layer.

### (Examples of Light Receiving Wavelength Bands)

The SOA 1 of the embodiments can provide a semiconductor light receiving element and a semiconductor optical signal amplifier using light emitting recombination centers.

The SOA 1 according to the embodiments can still achieve light reception even with respect to a long-wavelength light with an energy smaller than a band gap energy, and can function as a light receiving element for a long-wavelength light with an energy smaller than a band gap energy.

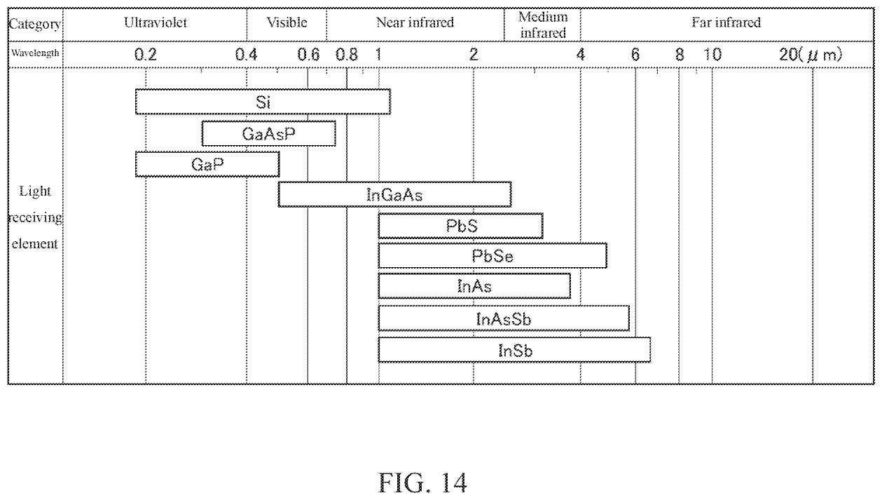

FIG. 14 shows examples of light-receiving wavelength bands determined according to transition between bands when individual semiconductor crystals are configured as light receiving elements. In FIG. 14, Si, GaAsP and GaP are indirect transition type semiconductor crystals. For Si, the light receiving wavelength band is approximately 0.18 μm to 1.1 μm. For GaAsP, the light receiving wavelength band is approximately 0.3 μm to 0.7 μm. For GaP, the light receiving wavelength band is approximately 0.18 μm to 0.5 μm.

In the SOA 1 of this embodiment, point defects that become light emitting recombination centers are introduced into the active layer, a light is amplified by transition via the energy levels, and so light receiving and optical amplification can be achieved even for a long-wavelength light with an energy smaller than a band gap energy of the active layer.

### (Diamond Crystals)

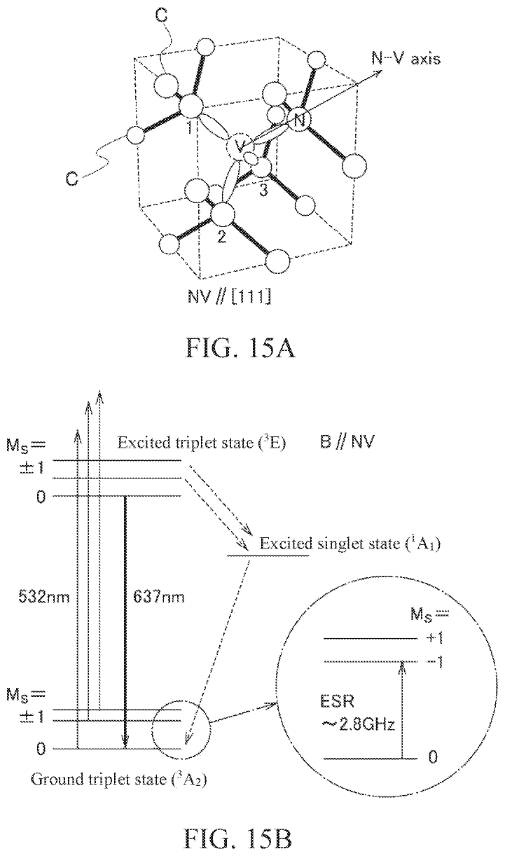

FIG. 15A shows a schematic structural diagram of a crystal structure of nitrogen-vacancy (NV) pairs (diamond NV centers) in a diamond crystal, and 15B shows a schematic diagram of energy levels in NV pairs (diamond NV centers) in a diamond crystal.

In the SOA of the embodiments, the indirect transition type semiconductor may also include diamond crystals. Herein, the point defect includes a defect in which a nitrogen atom N and an adjacent vacancy V are paired in the diamond crystals.

An N-V pair (a diamond NV center) in the diamond crystals serves as a defect in which a nitrogen atom N and an adjacent vacancy V are paired in the diamond crystals. A zero phonon line (light emitting transition that does not go through thermal exchange) is 637 nm. Stimulated emission (optical amplification) is performed via light excitation.

### (Manufacturing Method)

Defects are formed by injecting nitrogen ions into diamond crystal ions and performing heat treatment at above 600° C. Moreover, point defects may also be formed by injecting nitrogen ions into diamond crystal ions, introducing vacancy defects by electron beam irradiation and performing heat treatment. In addition, point defects may also be formed by injecting nitrogen ions into diamond crystal ions, introducing vacancies by irradiating femtosecond laser and performing local heat treatment by pulse laser. (SiC crystals)

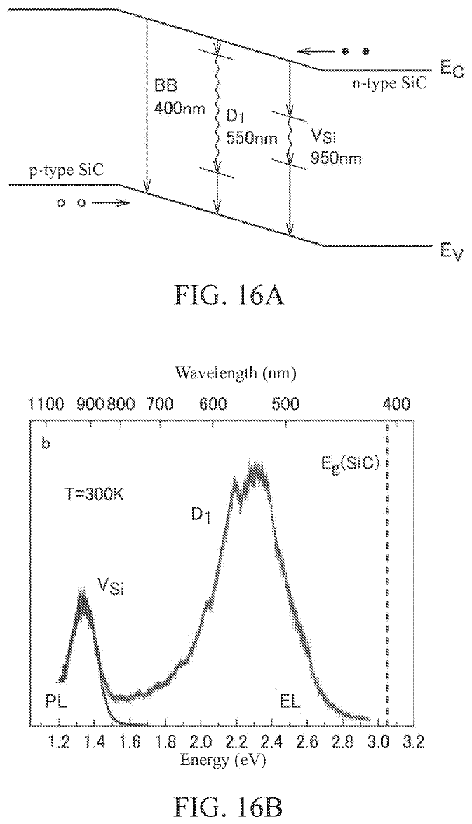

FIG. 16A shows a diagram of an energy gap structure and energy levels of a pn function of 6H—SiC having Si vacancy defects. In addition, FIG. 16B shows a diagram of measurement results (energy-wavelength dependency) of photoluminescence (PL) and electroluminescence (EL) of 6H—SiC having Si vacancy defects.

In the SOA of the embodiments, the indirect transition type semiconductor may also include SiC crystals. Herein, the point defect includes a defect in which a Si atom of a Si site in the SiC crystals is removed and becomes a hole. In addition, the SiC crystals include 4H—SiC or 6H—SiC.

The Si vacancy defect of 6H—SiC includes a defect in which a Si atom of a Si site is removed and becomes a hole. The zero phonon line is 1.4 eV (887 nm). The light emitting wavelength of transition between bands indicated by BB is 400 nm. D1 is light emission of other types of defects, and the light emitting wavelength is 550 nm. VSi represents light emission of a Si vacancy defect. The light emitting wavelength is 950 nm.

### (Manufacturing Method)

Si vacancy defects can be formed by irradiating with an electron beam with an acceleration voltage of 0.9 MeV at a dose of 10¹⁸/cm². Moreover, the Si vacancy defects can be formed by neutron beam irradiation, proton (H⁺) ion implantation, or femtosecond laser irradiation.

### (Divacancy Defects in 4H—SiC)

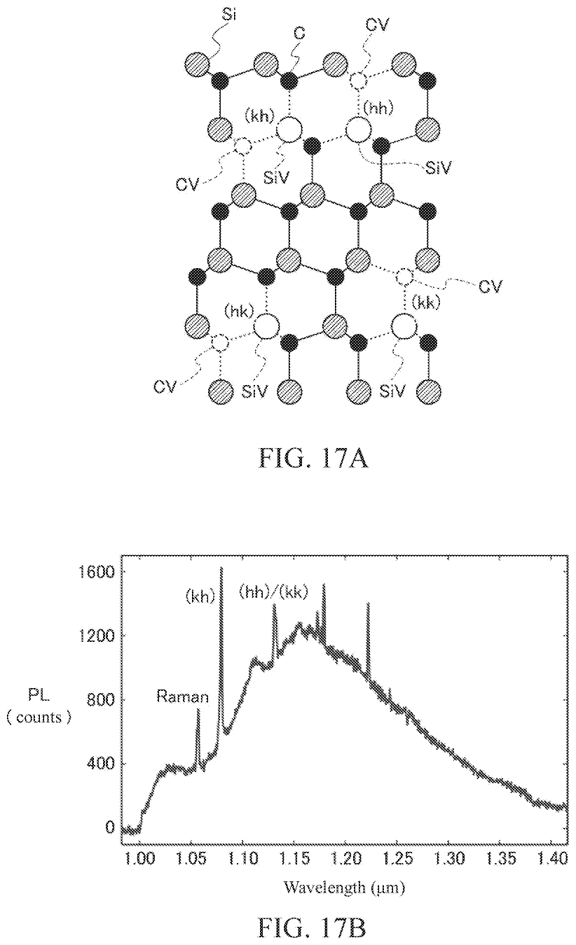

FIG. 17A shows a crystal structure of divacancy defects in 4H—SiC. In addition, FIG. 17B shows a diagram of measurement results (energy-wavelength dependency) of 20K photoluminescence (PL) of a pn function of 4H—SiC having divacancy defects. The divacancy defect includes a defect in which both adjacent Si and carbon (C) sites are vacant. The zero phonon line is 1.2 eV to 1.4 eV (1034 nm to 1129 nm).

In the semiconductor optical signal amplifier of the embodiments, the indirect transition type semiconductor may also include 4H—SiC crystals. In addition, the point defect includes a divacancy defect in which both adjacent Si and C sites in the 4H—SiC crystal are vacant.

### (Manufacturing Method)

Divacancy defects can be formed by irradiating 4H—SiC with an electron beam with an acceleration voltage of 2 MeV and a dose of 5×10¹² cm⁻² to 1×10¹⁵ cm⁻² in an argon (Ar) atmosphere for 30 minutes at 750° C.

### (Amorphous Si)

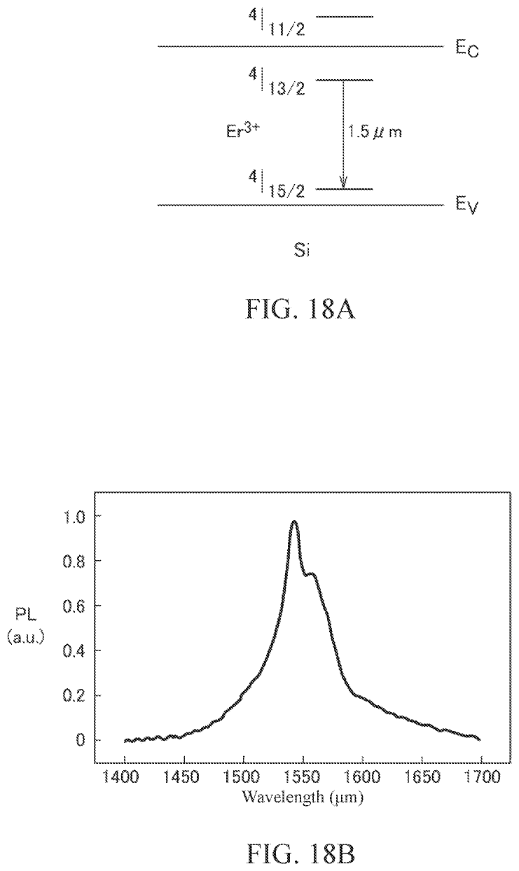

FIG. 18A shows energy levels formed by erbium ions (Er³⁺) in amorphous Si. FIG. 18B shows measurement results of PL formed by erbium ions (Er³⁺)) in amorphous Si.

A semiconductor optical signal amplifier of the embodiments includes: an active layer, made of an amorphous semiconductor that amplifies a signal intensity of an input light by stimulated emission; and a detection electrode, detecting a change in a carrier density in the active layer. The active layer has a point defect that serves as a recombination center forming an energy level in a band gap of the amorphous semiconductor, and a light with an energy smaller than a band gap energy of the amorphous semiconductor is amplified by transition via the energy level.

The amorphous semiconductor may include amorphous Si. Herein, the point defect is introduced into the amorphous Si by erbium ions (Er³⁺).

An optical amplifying medium has a light emitting recombination center formed in a band gap of the amorphous semiconductor.

The light recombination center has a point defect that forms an energy level in a band gap of the amorphous semiconductor.

The point defects realizes inverse distribution in the optical amplifying medium.

In the semiconductor optical signal amplifier of the embodiments, the amorphous semiconductor may also include amorphous Si. Herein, the point defect is introduced into the amorphous Si by erbium ions (Er³⁺).

(Light Emitting Wavelength of Erbium Ions (Er³⁺) in amorphous Si)

The zero phonon line is 1.2 eV to 1.4 eV (1034 nm to 1129 nm).

Stimulated emission may be performed by intense light excitation of more than 200 kW/cm². Moreover, it is confirmed that electrical driving can be achieved.

### (Manufacturing Method)

The point defect is formed by means of co-sputtering of silicon and erbium while amorphous silicon hydroxide is formed.

### (GaP)

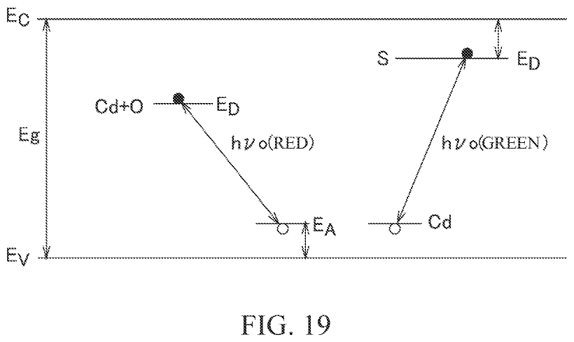

FIG. 19 shows energy levels when cadmium (Cd), cadmium (Cd)-oxygen (O) and sulfur (S) are added to GaP.

In the semiconductor optical signal amplifier of the embodiments, the indirect transition type semiconductor may also include GaP crystals. Herein, the point defect includes a composite defect of Cd, Cd—O and S added to GaP crystals.

In the Cd—O composite defect, a donor energy level E_{D} and an acceptor E_{A} as localized energy levels to become a light emitting recombination center, and an output light hvo (red) can be obtained.

In the Cd—S composite defect, a donor energy level E_{D} and an acceptor E_{A} as localized energy levels to become a light emitting recombination center, and an output light hvo (green) can be obtained.

### Other Embodiments

Some embodiments are described as above; however, it is to be understood that the discussion and drawings associated with part of the disclosure are illustrative rather than limitative. A person skilled in the art can understand various alternative implementations, examples and application techniques on the basis of the disclosure.

Therefore, the disclosure includes various other embodiments that are not described herein.

### INDUSTRIAL APPLICABILITY

The semiconductor optical signal amplifier of the embodiments is applicable to a wide range of fields including time of flight (TOF) ranging sensor systems, three-dimensional sensor systems, optical communications, vehicle sensors, NV center magnetic sensors, structural analysis of protein substances, intracellular measurement, cardiac magnetic measurement, brain magnetic measurement, Hall elements, and superconducting quantum interface devices (SQID).

1. A semiconductor optical signal amplifier, comprising:
an active layer, made of an indirect transition type semiconductor that amplifies a signal intensity of an input light by stimulated emission; and
a detection electrode, detecting a change in carrier density in the active layer, wherein
the active layer has a point defect that serves as a recombination center forming an energy level in a band gap of the indirect transition type semiconductor, and
a light with an energy smaller than a band gap energy of the indirect transition type semiconductor is amplified by transition via the energy level.

2. The semiconductor optical signal amplifier of claim 1, wherein the point defect includes a hole defect.

3. The semiconductor optical signal amplifier of claim 1, wherein the point defect includes a composite defect.

4. The semiconductor optical signal amplifier of claim 1, wherein the point defect is formed by impurities added to the indirect transition type semiconductor.

5. The semiconductor optical signal amplifier of claim 1, wherein
the indirect transition type semiconductor includes diamond crystals, and
the point defect includes a defect in which a nitrogen atom and a vacancy adjacent to the nitrogen atom are paired in the diamond crystals.

6. The semiconductor optical signal amplifier of claim 1, wherein
the indirect transition type semiconductor includes SiC (silicon carbide) crystals, and
the point defect includes a defect in which a Si (silicon) atom of a Si site in the SiC crystal is removed and becomes a hole.

7. The semiconductor optical signal amplifier of claim 6, wherein the SiC crystal includes 4H—SiC or 6H—SiC.

8. The semiconductor optical signal amplifier of claim 1, wherein
the indirect transition type semiconductor includes a 4H—SiC crystal, and
the point defect includes a defect in which both adjacent Si and C (carbon) sites in the 4H—SiC crystal are vacant.

9. The semiconductor optical signal amplifier of claim 1, wherein
the indirect transition type semiconductor includes a GaP (gallium phosphide) crystal, and
the point defect includes a composite defect of cadmium (Cd) and oxygen (O) in the GaP crystal.

10. A semiconductor optical signal amplifier, comprising:
an active layer, made of an amorphous semiconductor that amplifies a signal intensity of an input light by stimulated emission; and
a detection electrode, detecting a change in carrier density in the active layer, wherein
the active layer has a point defect that serves as a recombination center forming an energy level in a band gap of the amorphous semiconductor, and
a light with an energy smaller than a band gap energy of the amorphous semiconductor is amplified by transition via the energy level.

11. The semiconductor optical signal amplifier of claim 10, wherein
the amorphous semiconductor includes a amorphous Si (silicon), and
the point defect is introduced into the amorphous Si by Er³⁺ (erbium ion).

12. A semiconductor optical signal amplifier, comprising:
a first end face;
a second end face, arranged apart from the first end face;
a first semiconductor region of a first conductive type, arranged between the first end surface and the second end surface;
a second semiconductor region of a second conductive type opposite to the first conductive type, arranged between the first end face and the second end face;
an active layer, arranged between the first end surface and the second end surface, and sandwiched between the first semiconductor region and the second semiconductor region, wherein the active layer is made of an indirect transition type semiconductor that amplifies a signal intensity of an input light by stimulated emission; and
a first electrode, connected to the first semiconductor region;
a second electrode, connected to the second semiconductor region and detecting a change in carrier density in the active layer by a potential difference from the first electrode, wherein
the active layer has a point defect that serves as a recombination center forming an energy level in a band gap of the indirect transition type semiconductor, and
a light with an energy smaller than a band gap energy of the indirect transition type semiconductor is amplified by transition via the energy level.

13. The semiconductor optical signal amplifier of claim 12, wherein the second electrode includes a plurality of divided electrodes.

14. The semiconductor optical signal amplifier of claim 12, wherein the active layer has a band gap narrower than a band gap of the first semiconductor region and the second semiconductor region.

15. The semiconductor optical signal amplifier of claim 12, further comprising:
a first anti-reflective coating film, arranged on the first end surface; and
a second anti-reflective coating film, arranged on the second end face, wherein the first semiconductor region, the second semiconductor region and the active layer extend in a stripe shape from the first end surface toward the second end surface.

16. The semiconductor optical signal amplifier of claim 15, wherein the first end face and the second end face are parallel to each other and are inclined from the first end face toward the second end face.

17. The semiconductor optical signal amplifier of claim 12, wherein the active layer includes a window region in vicinity of the second end surface.

18. The semiconductor optical signal amplifier of claim 12, wherein the point defect includes a hole defect.

19. The semiconductor optical signal amplifier of claim 12, wherein the point defect includes a composite defect.

20. The semiconductor optical signal amplifier of claim 12, wherein the point defect is formed by impurities added to the indirect transition type semiconductor.
